(19) United States
(12) Patent Application Publication
(10) Pub. No.: US 2004/0004281 A1
(43) Pub. Date: Jan. 8, 2004

(54) Semiconductor package with heat sink

(76) Inventors: Jin-Chuan Bai, Hsinchu (TW); Cheng-Hui Lee, Hsinchu (TW)

Correspondence Address: FULBRIGHT AND JAWORSKI L L P, PATENT DOCKETING 29TH FLOOR, 865 SOUTH FIGUEROA STREET, LOS ANGELES, CA, 900172576

(21) Appl. No.: 10/264,544

(22) Filed: Oct. 4, 2002

(30) Foreign Application Priority Data
Jul. 3, 2002 (TW) 91114790

(51) Int. Cl. H01L 21/44; H01L 23/06

(52) U.S. Cl. 257/706; 257/705; 438/125; 438/122; 257/707; 257/719

(57) ABSTRACT

A semiconductor package with a heat sink is provided, wherein a substrate is formed with a metal core layer and at least an opening that penetrates through the substrate. At least a semiconductor chip is mounted on the substrate, with bond pads formed on the semiconductor chip being exposed to the opening, so as to allow the semiconductor chip to be electrically connected to the substrate by a plurality of gold wires that are bonded to the bond pads and formed through the opening. The metal core layer of the substrate provides a grounding plane to improve electrical quality of the semiconductor package, and acts as a heat sink to enhance heat-dissipating efficiency of the semiconductor package. Moreover, an encapsulant for encapsulating the semiconductor chip contains a plurality of thermally conductive metal particles to further facilitate dissipation of heat produced from the semiconductor chip.

### FIELD OF THE INVENTION

The present invention relates to semiconductor packages, and more particularly, to a semiconductor package with a substrate having a metal core layer, so as to enhance heat-dissipating efficiency and electrical quality of the semiconductor package.

### BACKGROUND OF THE INVENTION

Ball grid array (BGA) semiconductor packages are mainstream package products to be capable of providing sufficient input/output (I/O) connections for use with semiconductor chips incorporated with high density of electronic elements and electronic circuits. However, the highly integrated semiconductor chips with densely arranged electronic elements and circuits would produce relatively more heat during operation; if the heat can not be timely and effectively dissipated, performances and lifetime of the semiconductor chips would thus be damaged.

A way for resolving the above drawback is to mount a heat sink in a semiconductor package, in which the heat sink is attached to a semiconductor chip and encapsulated together with the semiconductor chip by an encapsulant, so as to improve heat-dissipating efficiency of the semiconductor package. However, heat produced from an active surface of the semiconductor chip needs to pass through the semiconductor chip, the heat sink and the encapsulant to be dissipated to the atmosphere; this thermally conductive path is considerably long and includes the encapsulant poor in thermal conductivity, making the heat-dissipating efficiency not able to be significantly enhanced as expected.

In response to the above problem and further to low profile of electronic products, U.S. Pat. No. 5,420,460 discloses a thin-type semiconductor package with a heat sink being exposed to outside of an encapsulant. As shown in FIG. 1, this semiconductor package 1 is of a thin cavity down ball grid array (TCDBGA) structure, wherein a heat sink 12 is formed at a central position thereof with a shallow cavity 121 facing downwardly, allowing a semiconductor chip 14 to be attached with its non-active surface 142 to the shallow cavity 121 by a thermally conductive adhesive 13 and encapsulated by an encapsulant 16. This structural arrangement provides a thermally conductive path that heat produced from the semiconductor chip 14 can rapidly pass through the thermally conductive adhesive 13 and the heat sink 12 to be dissipated to the atmosphere, thereby making heat-dissipating efficiency effectively improved for the semiconductor package 1.

However, during temperature cycles in package fabrication processes, since the semiconductor package 1 is thin in structure and mechanical strength of a substrate 11 is relatively small, thermal stress from the heat sink 12 is hardly eliminated and undesirably warps the substrate 11. This situation may further lead to cracks of the semiconductor chip 14 and delamination between the semiconductor chip 14 and heat sink 12, between the substrate 11 and heat sink 12 and between laminated layers in the substrate 11. Moreover, warpage of the substrate 11 would deteriorate planarity of the substrate 11 and adversely affect quality for bonding electronic components thereon.

Furthermore, as shown in FIG. 2, heat generated from a semiconductor chip 24 is dissipated in a radial-outward manner that, part of the heat goes through a heat sink 22 mounted on the semiconductor chip 24 for dissipation, but part of the heat is transmitted via a bottom surface of the semiconductor chip 24 and an adhesive 23 used for securing the semiconductor chip 24 in position to conductive traces 214 formed on a surface of a substrate 21, and further via a plurality of conductive vias 212 in the substrate 21 and solder balls 27 implanted on an opposing surface of the substrate 21 to a printed circuit board (PCB) 28. This thermally conductive path includes the adhesive 23 that is made of a resin material and absorbs humidity; as such, if moisture enters into the conductive vias 212 connected to the adhesive 23, it would be absorbed by the adhesive 23, making the adhesive 23 easily subject to interlayer swelling or popcorn effect problems in subsequent high-temperature fabrication processes, which problems occur particularly for directly mounting the semiconductor chip 24 over the conductive vias 212 of the substrate 21 or densely stacking electronic components in a semiconductor package.

Moreover, in order achieve high electric performance and high operational speed for electronic products, semiconductor chips are highly integrated and incorporated with high density of electronic circuits and electronic elements. However, if grounding circuits of the semiconductor chips can not be effectively improved as required for high integration, electric quality and yield of the semiconductor chips would be adversely affected.

### SUMMARY OF THE INVENTION

A primary objective of the present invention is to provide a semiconductor package with a heat sink, which can effectively dissipate heat produced by a semiconductor chip without increasing overall height of the semiconductor package.

Another objective of the present invention is to provide a semiconductor package with a heat sink, which can enhance mechanical strength of a substrate to prevent warpage of the substrate, and make moisture inside the substrate not absorbed by an adhesive used for mounting a semiconductor chip in the semiconductor package, so as to prevent the adhesive from being subject to popcorn effect or interlayer swelling problems, thereby assuring reliability of mounting of the semiconductor chip.

A further objective of the present invention is to provide a semiconductor package with a heat sink, wherein the heat sink acts as a grounding plane for improving electric quality of the semiconductor package, and provides electromagnetic shielding effect on a semiconductor chip so as to reduce external electromagnetic interference exerted to the semiconductor chip.

A further objective of the present invention is to provide a semiconductor package with a heat sink, wherein an encapsulant for encapsulating a non-active surface of a semiconductor chip is made of an encapsulating resin containing a plurality of metal particles having good thermal conductivity, so as to effectively dissipate heat produced from the semiconductor chip to outside of the semiconductor package.

In accordance with the above and other objectives, the present invention proposes a semiconductor package with a heat sink, comprising: a substrate having a first surface and a second surface opposed to the first surface, and formed with at least an opening penetrating through the first and second surfaces; at least a semiconductor chip having an active surface formed with a plurality of bond pads thereon, and a non-active surface opposed to the active surface, the semiconductor chip being mounted on the first surface of the substrate; a plurality of first conductive elements for electrically connecting the bond pads of the semiconductor chip to the second surface of the substrate; an encapsulant for encapsulating the semiconductor chip, the plurality of first conductive elements and part of the substrate; and a plurality of second conductive elements implanted on the second surface of the substrate, for electrically connecting the semiconductor package to an external device.

In the above semiconductor package, the second surface of the substrate is formed with a plurality of conductive traces, and implanted with the second conductive elements to be electrically connected to the external device. A barrier layer is deposited on the first surface of the substrate, and a metal core layer is disposed between the first and second surfaces of the substrate to act as a heat sink for the semiconductor package. With the opening being formed through the first and second surfaces of the substrate, the active surface of the semiconductor chip is attached with its peripheral portion to the first surface of the substrate around the opening by means of a thermally conductive adhesive, allowing the bond pads on the active surface of the semiconductor chip to be exposed to the opening of the substrate, such that the first conductive elements can be formed through the opening for electrically connecting the bond pads of the semiconductor chip to the conductive traces on the second surface of the substrate. This structural arrangement facilitates dissipation of heat produced from the semiconductor chip via the metal core layer of the substrate without increasing overall thickness of the semiconductor package. Moreover, since the conductive traces are merely formed on one surface (second surface) of the substrate, there is no need to fabricate conventional conductive vias for electrically interconnecting conductive traces formed on opposite surfaces of a substrate, thereby eliminating problems of interlayer swelling or popcorn effect in the case of an adhesive absorbing moisture entering into the conductive vias. Furthermore, the metal core layer of the substrate enhances mechanical strength of the substrate and thus prevents warpage of the substrate, thereby reinforcing structure of the semiconductor package. The metal core layer may act as a grounding plane to improve electrical quality of the semiconductor package; the metal core layer is located between the semiconductor chip and the external device, and may serve as an electromagnetic shield to reduce electromagnetic interference exerted to the semiconductor chip.

In addition, the encapsulant for encapsulating the chip can be made of a resin material containing a plurality of thermally conductive metal particles, so as to allow heat produced from the semiconductor chip to be dissipated to outside of the semiconductor package by the encapsulant that forms a heat-dissipating structure together with the metal core layer of the substrate to enhance heat-dissipating efficiency of the semiconductor package.

### BRIEF DESCRIPTION OF THE DRAWINGS

The present invention can be more fully understood by reading the following detailed description of the preferred embodiments, with reference made to the accompanying drawings, wherein:

FIG. 1 (PRIOR ART) is a cross-sectional view of a conventional semiconductor package disclosed in U.S. Pat. No. 5,420,460;

FIG. 2 (PRIOR ART) is a cross-sectional view of a conventional semiconductor package in a high-temperature fabrication process;

FIG. 3 is a cross-sectional view of a semiconductor package according to a first preferred embodiment of the invention; and

FIG. 4 is a cross-sectional view of a semiconductor package according to a second preferred embodiment of the invention.

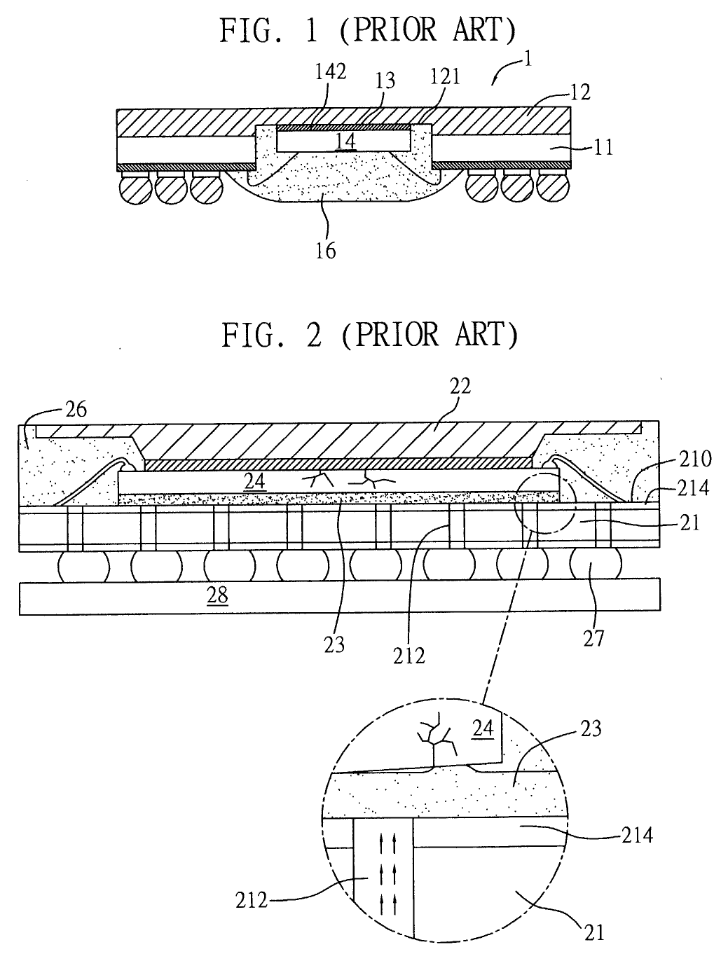

### DETAILED DESCRIPTION OF THE PREFERRED EMBODIMENTS

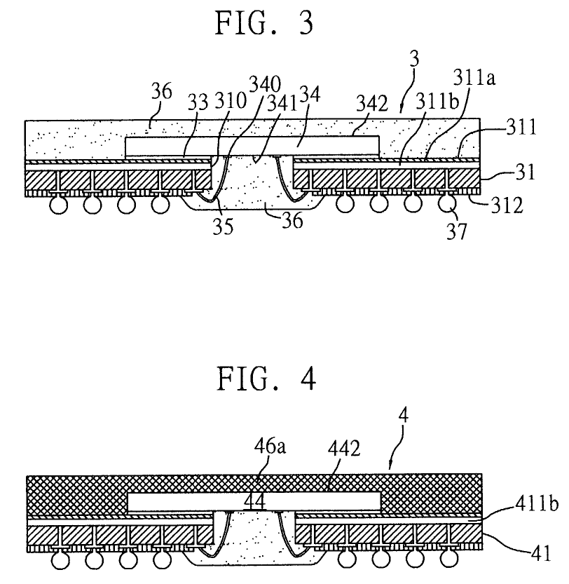

Preferred embodiments for a semiconductor package proposed in the present invention are described in more detail as follows with reference to FIGS. 3 and 4.

As shown in FIG. 3, the semiconductor package 3 of a first preferred embodiment of the invention is of a window ball grid array (WBGA) structure, and comprises: a substrate 31 having a first surface 311 and a second surface 312, and formed with at least a through opening 310, wherein a barrier layer 311a is deposited on the first surface 311, a plurality of conductive traces (not shown) are formed on the second surface 312, and a metal core layer 311b is disposed between the first and second surfaces 311, 312; at least a semiconductor chip 34 having an active surface 341 formed with a plurality of bond pads 340 thereon, and a non-active surface 342 opposed to the active surface 341 (“active surface” of a semiconductor chip is a surface where a plurality of electronic circuits and electronic elements are formed, and “non-active surface” is a surface not provided with electronic circuits and electronic elements thereon); a plurality of gold wires 35 for electrically connecting the semiconductor chip 34 to the substrate 31; an encapsulant 36 for encapsulating the semiconductor chip 34, the plurality of gold wires 35 and part of the substrate 31; and a plurality of solder balls 37 implanted on the second surface 312 of the substrate 31, for electrically connecting the semiconductor package 3 to an external device such as printed circuit board (PCB, not shown).

The substrate 31 is made of an organic resin material such as FR-4 resin, FR-5 resin or BT (bismaleimide triazine) resin. The substrate 31 has a first surface 311 and a second surface 312 opposed to the first surface 311. The first surface 311 of the substrate 31 is coated with a barrier layer 311a such as solder mask, and the second surface 312 of the substrate 31 is formed with a plurality of conductive traces (not shown) thereon. A metal core layer 311b is deposited by conventional plating technology between the first and second surfaces 311, 312 of the substrate 31, and acts as a heat sink for the semiconductor package 3. At least an opening 310 is formed through the first and second surfaces 311, 312 of the substrate 31, and is smaller in dimension than the semiconductor chip 34 but not interfering with a plurality of bond pads 340 formed on an active surface 341 of the semiconductor chip 34. The metal core layer 311b is of a thin plate structure made of copper, copper alloy, silver, silver alloy or other metallic materials with good thermal conductivity, and thereby can enhance mechanical strength of the substrate 31.

The semiconductor chip 34 has an active surface 341 formed with a plurality of bond pads 340 thereon, and a non-active surface 342 opposed to the active surface 341. The active surface 341 of the semiconductor chip 34 is attached with its peripheral portion to the first surface 31] of the substrate 3 1 around the opening 3 1 0 by means of a thermally conductive adhesive 33 in a manner that, the plurality of bond pads 340 on the active surface 341 of the semiconductor chip 34 are exposed to the opening 310 of the substrate 31, so as to allow the plurality of gold wires 35 formed through the opening 310 to electrically connect the exposed bond pads 340 of the semiconductor chip 34 to the conductive traces (not shown) on the second surface 3 l 2 of the substrate 3 1.

The encapsulant 36 is made of a resin material such as epoxy resin to be injected into an encapsulating mold (not shown), for encapsulating the non-active surface 342 of the semiconductor chip 34, part of the active surface 341, the plurality of gold wires 35 and part of the substrate 31, so as to protect these encapsulated components against external interference and contamination.

The plurality of solder balls 37 are implanted on the second surface 312 of the substrate 31, for electrically connecting the semiconductor chip 34 to an external device such as PCB (not shown). As a result, heat produced from the semiconductor chip 34 can rapidly pass through the thermally conductive adhesive 33 to the barrier layer 311a and the metal core layer (heat sink) 311b of the substrate 31, to be dissipated via the plurality of solder balls 37 implanted on the substrate 31 to outside of the semiconductor package 3. Moreover, the metal core layer 311b of the substrate 31 provides a satisfactory grounding plane for the semiconductor package 3, and is located between the semiconductor chip 34 and PCB (not shown), thereby acting as an electromagnetic shield to reduce electromagnetic interference exerted to the semiconductor chip 34 and assure electrical quality of the semiconductor package 3.

As shown in FIG. 4, a semiconductor package 4 of a second preferred embodiment of the invention is mostly the same in structure as the above semiconductor package 3 of the first preferred embodiment. The semiconductor package 4 differs from the above semiconductor package 3 in that, an encapsulant 46a for encapsulating a non-active surface 442 of a semiconductor chip 44 contains a plurality of metal particles (not shown) with good thermal conductivity, so as to allow heat produced from the semiconductor chip 44 to be dissipated through the encapsulant 46a that forms a satisfactory heat-dissipating structure together with a metal core layer 411b in a substrate 41. The metal particles can be made of copper, copper alloy, silver, silver alloy or other metallic materials with good thermal conductivity.

The invention has been described using exemplary preferred embodiments. However, it is to be understood that the scope of the invention is not limited to the disclosed embodiments. On the contrary, it is intended to cover various modifications and similar arrangements. The scope of the claims, therefore, should be accorded the broadest interpretation so as to encompass all such modifications and similar arrangements.

What is claimed is:

1. A semiconductor package with a heat sink, comprising:
a substrate having a first surface and a second surface opposed to the first surface, and formed with at least an opening penetrating through the first and second surfaces, wherein a barrier layer is deposited on the first surface, a plurality of conductive traces are formed on the second surface, and a thermally conductive metal core layer is disposed between the first and second surfaces of the substrate;
at least a semiconductor chip having an active surface formed with a plurality of bond pads thereon, and a non-active surface opposed to the active surface, the semiconductor chip being mounted on the first surface of the substrate;
a plurality of first conductive elements for electrically connecting the semiconductor chip to the substrate;
an encapsulant for encapsulating the semiconductor chip, the plurality of first conductive elements and part of the substrate; and
a plurality of second conductive elements implanted on the second surface of the substrate, for electrically connecting the semiconductor package to an external device.

2. The semiconductor package of claim 1, wherein the semiconductor package is a window ball grid array (WBGA) semiconductor package.

3. The semiconductor package of claim 1, wherein the active surface of the semiconductor chip is attached with a peripheral portion thereof to the first surface of the substrate around the opening by means of an adhesive, allowing the plurality of bond pads on the active surface of the semiconductor chip to be exposed to the opening of the substrate.

4. The semiconductor package of claim 3, wherein the adhesive is thermally conductive paste.

5. The semiconductor package of claim 1, wherein the first conductive elements are gold wires and penetrate through the opening of the substrate to electrically connect the bond pads of the semiconductor chip to the conductive traces on the second surface of the substrate.

6. The semiconductor package of claim 1, wherein the second conductive elements are solder balls.

7. The semiconductor package of claim 1, wherein the thermally conductive metal core layer of the substrate is made of a material selected from the group consisting of copper, copper alloy, silver, silver alloy and other metallic materials with good thermal conductivity, and the thermally conductive metal core layer acts as a heat sink and a grounding plane for the semiconductor package and enhances mechanical strength of the substrate.

8. The semiconductor package of claim 1, wherein the encapsulant for encapsulating the non-active surface of the semiconductor chip contains a plurality of metal particles with good thermal conductivity, so as to allow heat produced from the semiconductor chip to be dissipated to outside of the semiconductor package by the encapsulant that forms a heat-dissipating structure together with the metal core layer of the substrate for providing satisfactory heat-dissipating efficiency.

9. The semiconductor package of claim 8, wherein the metal particles are selected from the group consisting of copper, copper alloy, silver, silver alloy and other metallic materials with good thermal conductivity.
